(19) United States
(12) Patent Application Publication
(10) Pub. No.: US 2024/0015950 A1
(43) Pub. Date: Jan. 11, 2024

(54) SEMICONDUCTOR DEVICE AND METHOD FOR MANUFACTURING SEMICONDUCTOR DEVICE

(71) Applicant: Kioxia Corporation, Minato-ku (JP)

(72) Inventors: Masayuki MURASE, Yokkaichi Mie (JP); Kotaro NODA, Yokkaichi Mie (JP)

(73) Assignee: Kioxia Corporation, Minato-ku (JP)

(21) Appl. No.: 18/179,546

(22) Filed: Mar. 7, 2023

(30) Foreign Application Priority Data
Jul. 11, 2022 (JP) 2022-111463

(51) Int. Cl. H10B 12/00; H01L 29/66; H01L 29/786

(52) U.S. Cl. CPC H10B 12/33; H10B 12/036; H01L 29/66742; H01L 29/7869; H01L 29/78696

(57) ABSTRACT

A semiconductor device includes a channel filling a through via hole and including an oxide semiconductor; a first electrode disposed on the channel and formed of a conductive oxide; and a second electrode disposed on the first electrode and formed of a metal.

### CROSS-REFERENCE TO RELATED APPLICATION(S)

This application is based upon and claims the benefit of priority from Japanese Patent Application No. 2022-111463, filed Jul. 11, 2022, the entire contents of which are incorporated herein by reference.

### FIELD

Embodiments described herein relate generally to a semiconductor device and a method for manufacturing the semiconductor device.

### BACKGROUND

In recent years, a semiconductor device including a channel formed of an oxide semiconductor has been developed. For example, there is a dynamic random access memory (DRAM) in which an oxide semiconductor transistor is used as a switching transistor of a memory cell.

### DESCRIPTION OF THE DRAWINGS

FIG. 1 is a schematic cross-sectional view illustrating a configuration example of a semiconductor memory device.

FIG. 2 is a schematic cross-sectional view illustrating a part of the configuration example of the semiconductor memory device.

FIG. 3 is a schematic cross-sectional view illustrating an example of a method for manufacturing a semiconductor memory device.

FIG. 4 is a plan view illustrating an example of the method for manufacturing a semiconductor memory device.

FIG. 5 is a schematic cross-sectional view illustrating an example of the method for manufacturing a semiconductor memory device.

FIG. 6 is a plan view illustrating an example of the method for manufacturing a semiconductor memory device.

FIG. 7 is a schematic cross-sectional view illustrating a configuration example of a semiconductor memory device in a comparative example.

FIG. 8 is a schematic cross-sectional view illustrating an example of a method for manufacturing a semiconductor memory device.

### DETAILED DESCRIPTION

Embodiments provide a semiconductor device configured to facilitate oxygen supply to a channel formed of an oxide semiconductor by annealing.

In general, according to one embodiment, a semiconductor device includes a channel filling a through via hole and including an oxide semiconductor; a first electrode disposed on the channel and formed of a conductive oxide; and a second electrode disposed on the first electrode and formed of a metal.

Hereinafter, embodiments of the present disclosure will be described with reference to the drawings. In the following description, the same or similar components are denoted by the same reference numerals, and the description thereof may be omitted.

For the sake of convenience of the description, the term “on” or “under” may be used herein. However, the term is used for description of a relative position in the drawings, and the term may differ from up or down in a vertical direction.

A semiconductor memory device of the embodiment is a dynamic random access memory (DRAM) and includes a memory cell array including a plurality of memory cells. The memory cells each include a field-effect transistor (FET) and a capacitor. The memory cells are arranged in a matrix and constitute the memory cell array. The memory cells may be arranged in a matrix and vertically in a plurality of layers. A gate of the field-effect transistor constituting each of the memory cells is connected to a corresponding word line, one of a source and a drain of the field-effect transistor is connected to one electrode of the capacitor, and the other of the source and the drain of the field-effect transistor is connected to a corresponding bit line. The one electrode of the capacitor is connected to the one electrode of the field-effect transistor as describe above. The other electrode of the capacitor is connected to a power supply line that supplies a predetermined potential. The memory cells store data by accumulating charges in the capacitor through the bit line according to the switching of the field-effect transistor by the word line. A semiconductor memory device 1 according to the embodiment is an example of the semiconductor device.

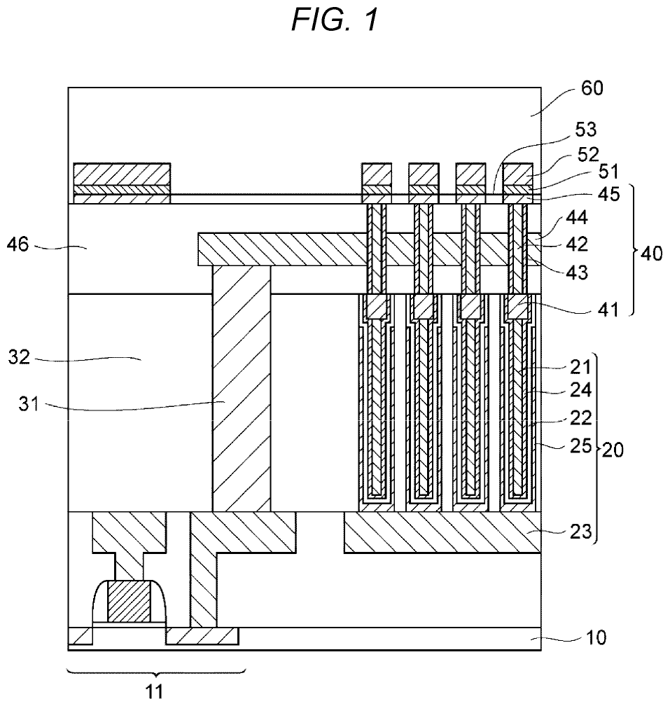

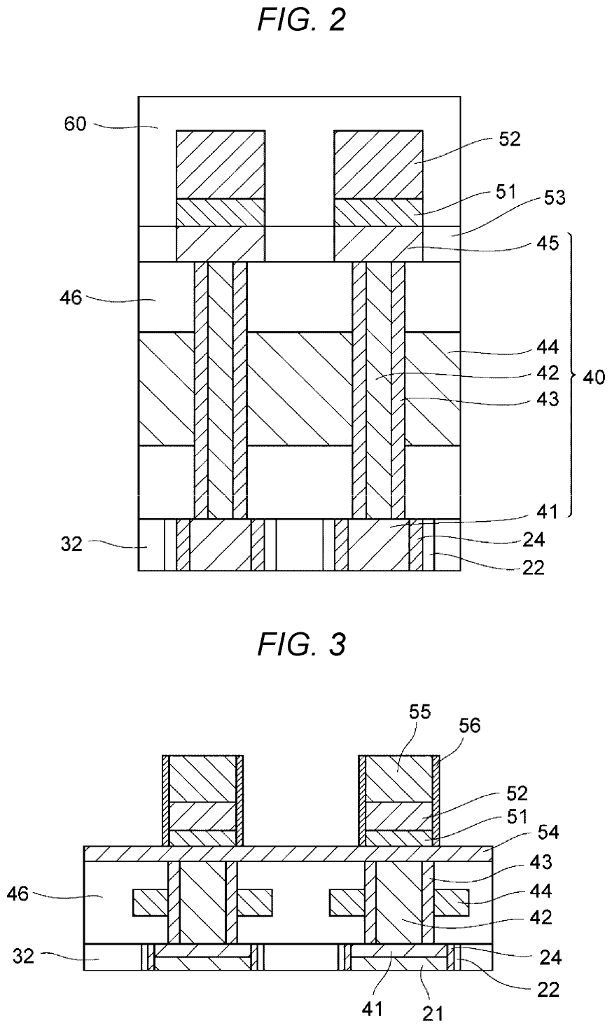

FIG. 1 is a schematic cross-sectional view illustrating a configuration example of the semiconductor memory device 1 according to the embodiment. FIG. 2 is a schematic cross-sectional view illustrating a part of FIG. 1. As shown in FIG. 1, the semiconductor memory device 1 includes a semiconductor substrate 10, a semiconductor element 11, a first capacitor electrode 21, a dielectric body 22, a second capacitor electrode 23, a conductor 24, a conductor 25, a conductor 31, an insulating layer 32, a lower electrode 41, an oxide semiconductor layer 42, a gate oxide film 43, a word line 44, an upper electrode 45, an insulating layer 46, a barrier metal 51, a landing pad 52, an insulating film 53, and an insulating layer 60.

For example, the semiconductor substrate 10 is a substrate formed of a single crystal silicon and the like.

The semiconductor element 11 is a metal-oxide-semiconductor field-effect transistor (MOSFET) and the like formed on the semiconductor substrate 10, but may be another semiconductor element. For example, the semiconductor element 11 constitutes a semiconductor integrated circuit.

The first capacitor electrode 21, the dielectric body 22, the second capacitor electrode 23, the conductor 24, and the conductor 25 constitute a capacitor 20. The capacitor 20 is a component of each of the memory cells. FIG. 1 illustrates four capacitors 20. The number of capacitors 20 may be optionally changed.

The capacitor 20 of the embodiment is a three-dimensional capacitor, such as a so-called pillar-type capacitor or a cylinder-type capacitor. The capacitor 20 includes the conductor 24, the dielectric body 22, and the conductor 25 between the first capacitor electrode 21 and the second capacitor electrode 23 and accumulates charges between the electrodes.

The first capacitor electrode 21 contains, for example, a material such as amorphous silicon. The second capacitor electrode 23, the conductor 24, and the conductor 25 contain, for example, a material such as tungsten (W) or titanium nitride (TiN). The dielectric body 22 is an insulator and contains, for example, a material such as hafnium oxide.

The lower electrode 41, the oxide semiconductor layer 42, the gate oxide film 43, the word line 44, and the upper electrode 45 constitute a field-effect transistor 40. The field-effect transistor 40 is formed on the capacitor 20. The field-effect transistor 40 is a component of each of the memory cells. FIGS. 1 and 2 illustrate four field-effect transistors corresponding to the four capacitors 20. The number of field-effect transistors 40 may be optionally changed according to the number of capacitors 20.

The lower electrode 41 is disposed on the first capacitor electrode 21 and electrically connected to the first capacitor electrode 21. The lower electrode 41 contains, for example, a metal oxide such as indium tin oxide (ITO).

The oxide semiconductor layer 42 is disposed in the through via hole formed between the lower electrode 41 and the upper electrode 45 and vertically extends in a columnar shape. For example, the oxide semiconductor layer 42 is an oxide containing indium (In), gallium (Ga), and zinc (Zn), or IGZO. The oxide semiconductor layer 42 forms a channel of the field-effect transistor 40.

The gate oxide film 43 is disposed between the oxide semiconductor layer 42 and the word line 44 so as to cover the periphery of the oxide semiconductor layer 42. The gate oxide film 43 is an insulator and contains, for example, silicon and oxygen.

The word line 44 is a word line in the memory cells and forms a gate electrode of the field-effect transistor 40. For example, the word line 44 is a conductor containing at least one material selected from the group consisting of tungsten (W), titanium (Ti), titanium nitride (TiN), molybdenum (Mo), cobalt (Co), and ruthenium (Ru). Typically, the word line 44 is formed of tungsten. The word line 44 is an example of a “control electrode”.

The upper electrode 45 is disposed on the oxide semiconductor layer 42. The upper electrode 45 is a conductor containing a conductive oxide and contains, for example, a metal oxide such as indium tin oxide (ITO). The upper electrode 45 is an example of the “first electrode”.

The upper electrode 45 functions as one of the source electrode and the drain electrode of the field-effect transistor 40. The lower electrode 41 functions as the other of the source electrode and the drain electrode of the field-effect transistor 40.

When a predetermined potential difference is generated between the word line 44 functioning as the gate electrode and the source electrode or the drain electrode in the field-effect transistor 40 of the semiconductor memory device 1, an electric field is generated at a channel region of the oxide semiconductor layer 42, and a current flows from the source electrode to the drain electrode. The word line 44 is also the control electrode that generates an electric field in the oxide semiconductor layer 42 that becomes the channel.

The barrier metal 51 is disposed on the upper electrode 45 so as to cover the upper electrode 45. For example, the barrier metal 51 is formed of a conductor such as tantalum (Ta) or tantalum nitride (TaN). The barrier metal 51 has lower oxygen permeability than the upper electrode 45. The barrier metal 51 is an example of the “second electrode”.

The landing pad 52 is formed on the barrier metal 51 and functions as the bit line of each of the memory cells. For example, the landing pad 52 is formed of a conductor such as tungsten (W).

For example, the conductor 31 electrically connects the memory cells to the semiconductor element 11. The conductor 31 functions as a so-called via. For example, the conductor 31 is formed of copper and the like.

The insulating layer 32 is an insulator that electrically insulates the capacitors 20 from each other in a layer including the capacitors 20. For example, the insulating layer 32 is formed of silicon nitride (SiN) and the like.

The insulating layer 46 is an insulator disposed in a layer including the oxide semiconductor layer 42 and the like. For example, the insulating layer 46 is formed of silicon oxide (SiO₂) and the like that are formed by a process such as CVD using a gas such as tetraethoxysilane (TEOS).

The insulating film 53 is an insulator that is the same layer as the upper electrode 45 and is disposed around the upper electrode 45, and electrically insulates the upper electrode 45 from another upper electrode 45. The insulating film 53 contains at least one metal element selected from magnesium (Mg), vanadium (V), chromium (Cr), manganese (Mn), iron (Fe), cobalt (Co), nickel (Ni), and bismuth (Bi) in addition to a metal oxide such as indium tin oxide (ITO) that is the same as the upper electrode 45.

The insulating film 53 is an insulator formed by ion implantation of the metal such as magnesium in a process after formation of indium tin oxide and the like in a production process. The insulator is different from the upper electrode 45 that is a conductor. That is, the insulating film 53 is formed so as to physically continue the upper electrode 45 and functions as an insulator by doping with (implantation of) the metal such as magnesium. For the insulating film 53, the metal that is implanted in a film of a metal oxide such as indium tin oxide is not limited to the metal such as magnesium, and is not limited as long as it is a material that enhances the electric resistance of the metal oxide film by implantation in the metal oxide film to form a substantial insulator.

The insulating layer 60 is an insulator formed on the upper electrode 45 and electrically insulates the landing pad 52 and the barrier metal 51 from an adjacent landing pad 52 and an adjacent barrier metal 51. The insulating layer 60 contains, for example, silicon and oxygen.

Method for Manufacturing Semiconductor Memory Device 1

Next, a characteristic part in the embodiment in a method for manufacturing the semiconductor memory device 1 will be described.

An existing method for manufacturing a semiconductor device may be used in steps except for the steps described below.

FIG. 3 illustrates a state before formation of the upper electrode 45 and the insulating film 53 on the oxide semiconductor layer 42 and the insulating layer 46. The oxide semiconductor layer 42 and the gate oxide film 43 are formed in the through via hole formed in the insulating layer 46. A conductor 54 is layered on the oxide semiconductor layer 42, the gate oxide film 43, and the insulating layer 46. In that case, the conductor 54 is formed on the whole surface thereof. Therefore, the oxide semiconductor layer 42 is electrically connected to other oxide semiconductor layers 42 through the conductor 54.

Furthermore, the barrier metal 51, the landing pad 52, a coating 55, and a liner film 56 are formed on the conductor 54. The coating 55 is formed on the landing pad 52. The liner film 56 surrounds the barrier metal 51, the landing pad 52, and the coating 55. Although the coating 55 is not shown in FIGS. 1 and 2, the coating 55 may be included as shown in FIG. 3. Alternatively, the coating 55 may not be included.

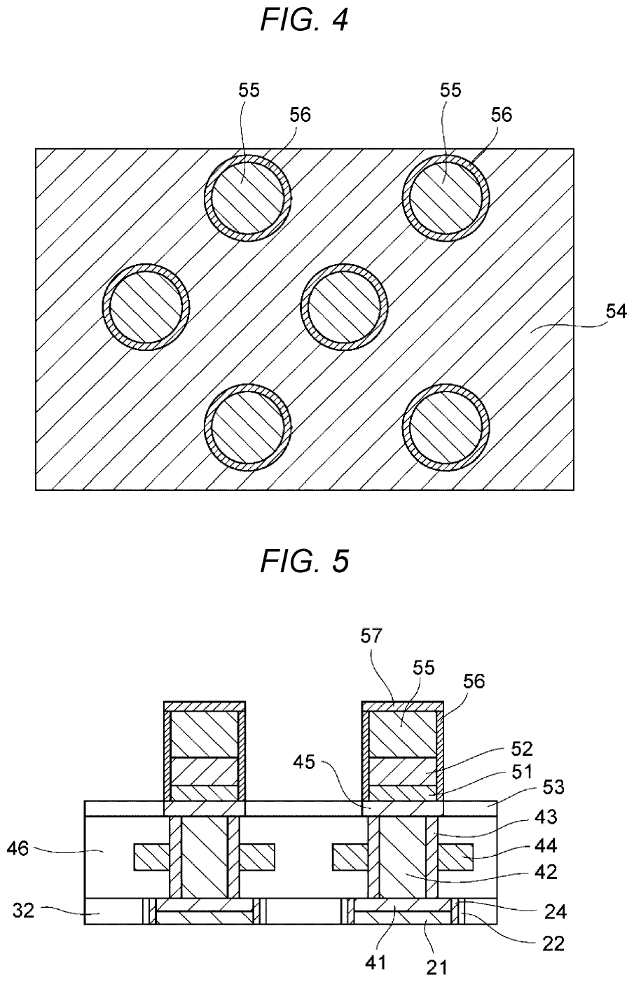

FIG. 4 is a plan view as viewed from the top of the semiconductor memory device during production as shown in FIG. 3. The liner film 56 that is annular is formed around the coating 55 that is circular. Sets of the coating 55 and the liner film 56 are disposed in a staggered manner.

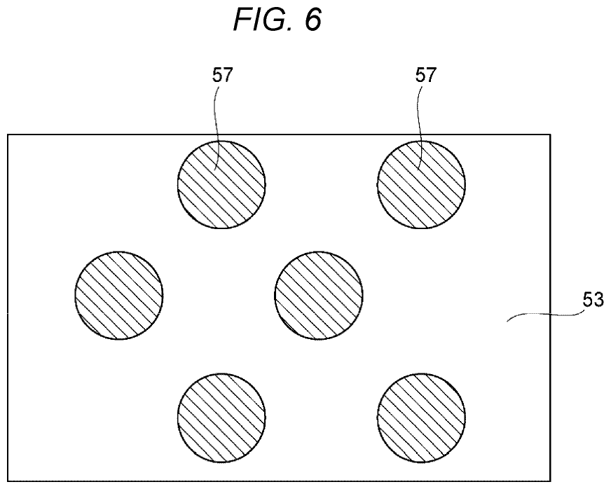

In a state shown in FIGS. 3 and 4, a material for doping (to be implanted), such as magnesium, is supplied to the conductor 54. Thus, ion implantation is carried out. As shown in FIG. 5, the upper electrode 45, the insulating film 53, and a coating 57 are formed. The upper electrode 45 is formed of the same material as the conductor 54 without implanting magnesium and the like. In the insulating film 53, resistance is increased by implantation of magnesium and the like in the conductor 54, so that the insulating film 53 is an insulator. Thus, the upper electrode 45 is electrically insulated from an adjacent upper electrode 45, and the oxide semiconductor layer 42 is electrically insulated from another oxide semiconductor layer 42. The coating 57 is the coating 55 and the liner film 56 in which magnesium and the like are implanted.

A material to be implanted in the conductor 54 may be optionally selected as long as it is a material that can substantially form an insulator by being implanted in a metal oxide such as indium tin oxide and increasing the electric resistance of the metal oxide. Specifically, the material to be implanted in the conductor 54 contains at least one metal element selected from magnesium (Mg), vanadium (V), chromium (Cr), manganese (Mn), iron (Fe), cobalt (Co), nickel (Ni), and bismuth (Bi). It is preferable that magnesium (Mg) be implanted in the conductor 54.

For example, “Research and Development KOBE STEEL ENGINEERING REPORTS, Vol. 48, No. 3, pp. 39 to 42, Impurity Effects on Indium Oxide Electronic States” suggests that by doping In₂O₃ with Mg, an acceptor level is formed. “APPLIED PHYSICS LETTERS 101, 102107 (2012), Mg acceptor doping of In₂O₃ and overcompensation by oxygen vacancies” describes that by implanting Mg in In₂O₃, an increase in resistance ratio is observed. A research group in Nagoya University reports a research result in which a p-type crystal is formed by implantation of Mg in GaN the ionization energy of which is relatively close to that of In₂O₃ (https://www.nagoya-u.ac.jp/about-nu/public-relations/researchinfo/upload images/20190528 imass001.pdf).

In addition to study and investigation by the present inventors, the aforementioned research results show that by implantation of Mg in In₂O₃, the resistance ratio is increased and the resultant functions as an insulator.

From “Physics Review B 79.165202 (Published 8 Apr. 2009), Electronic structure, donor and acceptor transitions, and magnetism of 3d impurities in In₂O₃ and ZnO” and “Physics Review Materials 3, 034605 (Published 15 Mar. 2019), Enabling visible-light absorption and p-type doping in In₂O₃ by adding Bi”, it is estimated that even when V, Cr, Mn, Fe, Co, Ni or Bi is used in place of Mg, the element can function as an acceptor. In addition to the study and investigation by the present inventors, the aforementioned research results show that even when at least one element selected from V, Cr, Mn, Fe, Co, Ni, and Bi is implanted in In₂O₃, the resultant functions as an insulator.

FIG. 6 is a plan view as viewed from the top of the semiconductor memory device during production shown in FIG. 5. The conductor 54 is formed under the coating 57, and the insulating film 53 is formed around the coating 57.

In a state shown in FIG. 6, oxygen annealing by heating is carried out for supplying oxygen to the oxide semiconductor layer 42 for activation.

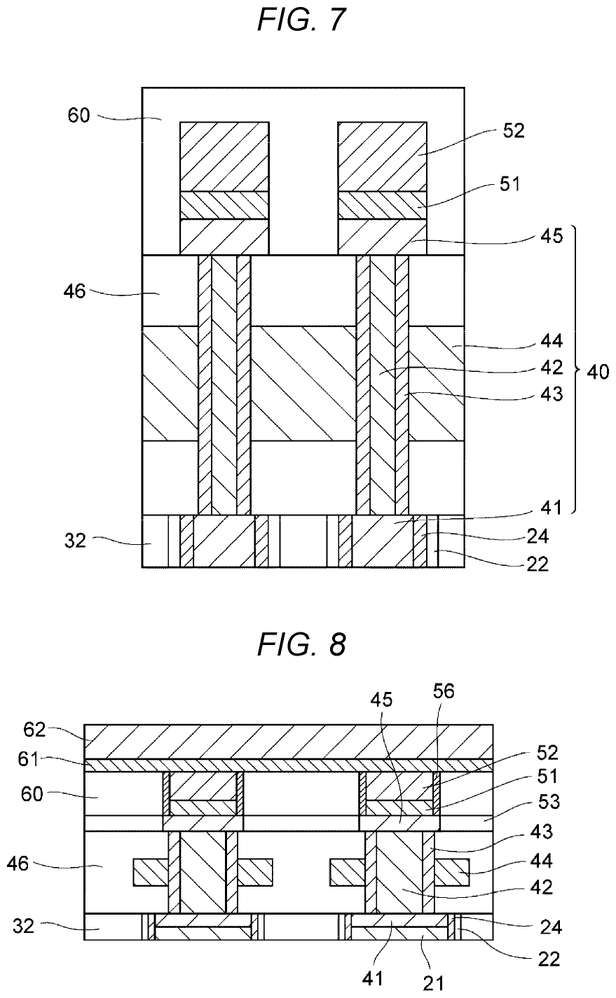

In a case of a configuration in a comparative example shown in FIG. 7 in which the insulating film 53 is not included, oxygen does not pass through the barrier metal 51. Therefore, a route of oxygen supplied to the oxide semiconductor layer 42 is only from a side wall of the upper electrode 45. For example, the side wall of the upper electrode 45 has a height of about 5 nm, and therefore supplied oxygen is restricted, and it takes a long time to fully supply oxygen to the oxide semiconductor layer 42.

In the configuration shown in FIG. 2 of the embodiment, the insulating film 53 allows oxygen to pass therethrough, and therefore the route of oxygen supplied to the oxide semiconductor layer 42 is in the insulating film 53 and the upper electrode 45. This route allows for efficient supply of oxygen to the oxide semiconductor layer 42 as compared with the configuration of the comparative example shown in FIG. 7, and the time required for sufficient supply of oxygen to the oxide semiconductor layer 42 can be shortened.

After oxygen annealing in the state shown in FIG. 6, the coating 55 and the coating 57 are removed, and the insulating layer 60, a first bit line 61, and a second bit line 62 are formed. As a result, the semiconductor memory device 1 shown in FIG. 8 can be manufactured.

In FIG. 8, for example, the first bit line 61 is formed of a conductor such as titanium nitride. For example, the second bit line 62 is formed of a conductor such as tungsten.

Hereinabove, the embodiment is described with reference to specific examples. However, the disclosure is not limited to the specific examples. The specific examples to which design changes are made by a person skilled in the art as appropriate are encompassed in the scope of the disclosure as long as the features of the disclosure are included. The components and the arrangements thereof, the conditions, the shapes, and the like included in the specific examples are not limited to those exemplified and may be changed as appropriate. The combination of the components included in the specific examples may be changed as appropriate as long as technical contradiction does not occur.

For example, the configuration of the present disclosure is not limited to the semiconductor memory device 1 of the embodiment and may be a semiconductor device including the oxide semiconductor layer 42 that is disposed in the through via hole and functions as the channel formed of an oxide semiconductor, the upper electrode 45 disposed on the channel and is a conductive oxide, and the barrier metal 51 disposed on the upper electrode 45. That is, the configuration is not necessarily a memory device.

A layered structure in the embodiment is merely an example. For example, the layered structure may be a layered structure that is different from that in the embodiment and has the upper electrode 45, the barrier metal 51 disposed on the upper electrode 45, and the insulating film 53 that is disposed adjacent to the upper electrode 45 and becomes an insulator by the use of the same material as that for the upper electrode 45 and implantation of any element.

The semiconductor memory device 1 of the embodiment may be a semiconductor device in which a plurality of capacitors and field-effect transistors 40 are disposed in a layering direction.

Although the semiconductor memory device 1 of the embodiment has a configuration including the capacitor 20 to function as a memory device, the semiconductor memory device 1 may be a semiconductor device including no capacitor 20.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a channel filling a through via hole and including an oxide semiconductor;
a first electrode disposed on the channel and formed of a conductive oxide; and
a second electrode disposed on the first electrode and formed of a metal.

2. The semiconductor device according to claim 1, further comprising:
an insulating film disposed around the first electrode, including the conductive oxide, and having insulating properties.

3. The semiconductor device according to claim 2, wherein the first electrode and the insulating film are disposed in one layer.

4. The semiconductor device according to claim 1, wherein the first electrode has higher oxygen permeability than the second electrode.

5. The semiconductor device according to claim 2, wherein the first electrode and the insulating film have higher oxygen permeability than the second electrode.

6. The semiconductor device according to claim 2, wherein the conductive oxide includes O, In, and Sn, and the insulating film further includes at least one element selected from Mg, V, Cr, Mn, Fe, Co, Ni, and Bi.

7. The semiconductor device according to claim 1, further comprising:
a semiconductor substrate; and
a capacitor disposed on the semiconductor substrate and electrically connected to the channel.

8. The semiconductor device according to claim 7, further comprising:
an insulating film disposed around the channel;
a control electrode configured to generate an electric field in the channel; and
a semiconductor element disposed on the semiconductor substrate and electrically connected to the control electrode.

9. A method for manufacturing a semiconductor device comprising:
forming, in a first through via hole extending through an insulating layer, a first channel including a first oxide semiconductor;
forming, in a second through via hole also extending through the insulating layer, a second channel including a second oxide semiconductor;
forming, over the insulating layer, a conductive film including a conductive oxide;
doping, with a metal, at least one region of the conductive film that does not overlay the first channel and the second channel; and
annealing the doped conductive film under oxygen.

10. The method for manufacturing a semiconductor device according to claim 9, wherein the step of doping at least one region of the conductive film includes electrically insulating the first channel from the second channel.

11. The method for manufacturing a semiconductor device according to claim 9, wherein the metal is selected from a group consisting of: Mg, V, Cr, Mn, Fe, Co, Ni, Bi, and combinations thereof.

12. The method for manufacturing a semiconductor device according to claim 9, wherein the conductive oxide includes indium tin oxide.

13. The method for manufacturing a semiconductor device according to claim 9, prior to doping at least one region of the conductive film, further comprising:
overlaying a first region of the conductive film directly above the first channel with at least a first landing pad;
overlaying a second region of the conductive film directly above the second channel with at least a second landing pad;
covering sidewalls and a top surface of the first landing pad; and
covering sidewalls and a top surface of the second landing pad.

14. The method for manufacturing a semiconductor device according to claim 13, wherein the at least one doped region is different from the first or second region.
